(19) United States
(12) Patent Application Publication
(10) Pub. No.: US 2010/0328142 A1
(43) Pub. Date: Dec. 30, 2010

(54) MICROWAVE AND MILLIMETER WAVE RESONANT SENSOR HAVING PERPENDICULAR FEED, AND IMAGING SYSTEM

(75) Inventors: Reza Zoughi, Wildwood, MO (US); Sergiy Kharkivskiy, Rolla, MO (US); Mohammad Tayeb Ahmad Ghasr, Rolla, MO (US); Mohamed Ahmed AbouKhousa, London (CA)

Correspondence Address: SENNIGER POWERS LLP, 100 NORTH BROADWAY, 17TH FLOOR, ST LOUIS, MO, 63102, US

(73) Assignee: THE CURATORS OF THE UNIVERSITY OF MISSOURI, Columbia, MO (US)

(21) Appl. No.: 12/816,219

(22) Filed: Jun. 15, 2010

Related U.S. Application Data
(63) Continuation-in-part of application No. 12/052,589, filed on Mar. 20, 2008, now Pat. No. 7,746,266.

(51) Int. Cl. G01S 13/89; G01R 29/00

(52) U.S. Cl. 342/179; 324/76.11

(57) ABSTRACT

A switched-slot sensor for use in a sensor array for microwave and/or millimeter wave imaging. The locations of a plurality of sensors in the array define a spatial domain away from an object for detecting an electric field from the object. Each of the sensors has an out-of-plane transmission line and outputs a signal representative of the measured field and the location of the sensor. A processor decodes the signals and generates an image of the object.

### CROSS-REFERENCE TO RELATED APPLICATION

This application is a Continuation-in-Part of U.S. patent application Ser. No. 12/052,589, filed Mar. 20, 2008, the entire disclosure of which is incorporated herein by reference.

### STATEMENT OF GOVERNMENT INTEREST

The U.S. Government has a paid-up license and the right in limited circumstances to require the patent owner to license others on reasonable terms as provided by the terms of grant number N00014-09-1-0369 awarded by the Office of Naval Research.

### BACKGROUND

Non-destructive, real-time imaging known in the art uses electromagnetic radiation to detect properties of an object under inspection. Generally, an electromagnetic field source illuminates the object and an array of sensor elements receives the electric field scattered by the object. Each sensor signal typically requires separate pickup circuitry for discriminating one signal from another. For example, conventional modulated scattering techniques (MST) for imaging use inefficient dipole antennas to sample the field and, thus, are not sufficiently sensitive, particularly for fields at higher frequencies. Switched antenna array techniques for imaging require expensive and bulky radio frequency (RF) circuitry for each pickup antenna to detect the electromagnetic field from each array element's location. Unfortunately, such conventional switched antenna array imaging does not provide sufficient resolution, particularly at higher frequencies.

Moreover, further improvements to enhance signal-to-noise ratio (SNR) are desired.

### SUMMARY

Imaging systems and methods embodying aspects of the invention provide an array of switched-slot sensors receiving and responsive to microwave and/or millimeter wave electromagnetic radiation. The locations of the sensors in the array define a spatial domain away from an object for detecting an electromagnetic field scattered by the object. Each of the sensors outputs a signal representative of the detected field and the location of the sensor. By decoding the signals, an image of the object can be generated. Aspects of the invention permit high measurement sensitivity, high spatial resolution, real-time operation, portability, and improved SNR.

This summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Other features will be in part apparent and in part pointed out hereinafter.

### BRIEF DESCRIPTION OF THE DRAWINGS

FIG. 1 illustrates a microwave and millimeter wave imaging system embodying aspects of the invention.

FIG. 2A illustrates an exemplary sensor suitable for use in an array of the system of FIG. 1.

FIG. 2B illustrates another exemplary sensor suitable for use in an array of the system of FIG. 1.

FIGS. 3A and 3B illustrate a side view and a top view, respectively, of the sensor of FIG. 2B having an out-of-plane transmission line for electrically coupling a feed thereto.

FIGS. 4A and 4B illustrate a side view and a top view, respectively, of the sensor of FIG. 2B having an out-of-plane transmission line with an inline switch and an impedance transformer for electrically coupling a feed thereto.

FIG. 5 illustrates an exemplary circuit diagram of DC bias of a PIN diode incorporated in the out-of-plane transmission line.

FIG. 6A illustrates the sensor of FIG. 2B having an out-of-plane coaxial transmission line for electrically coupling a feed thereto.

FIG. 6B illustrates the sensor of FIG. 2B having an out-of-plane coaxial transmission line for electromagnetically coupling a feed thereto.

FIGS. 7A and 7B illustrate exemplary positions of an array of sensors according to embodiments of the invention.

Corresponding reference characters indicate corresponding parts throughout the drawings.

### DETAILED DESCRIPTION

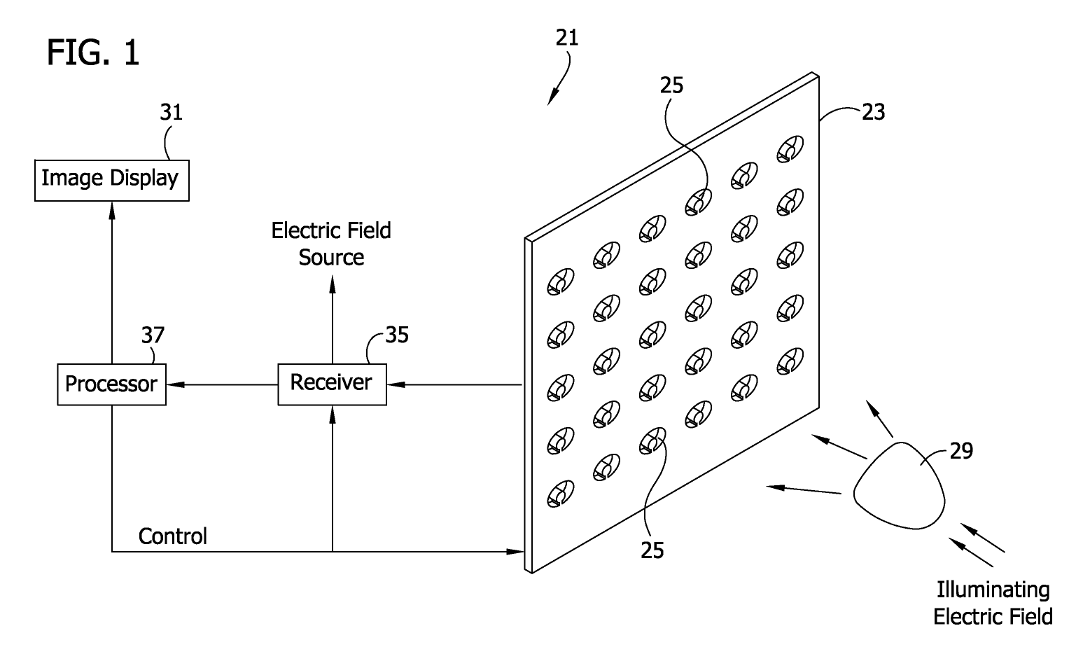

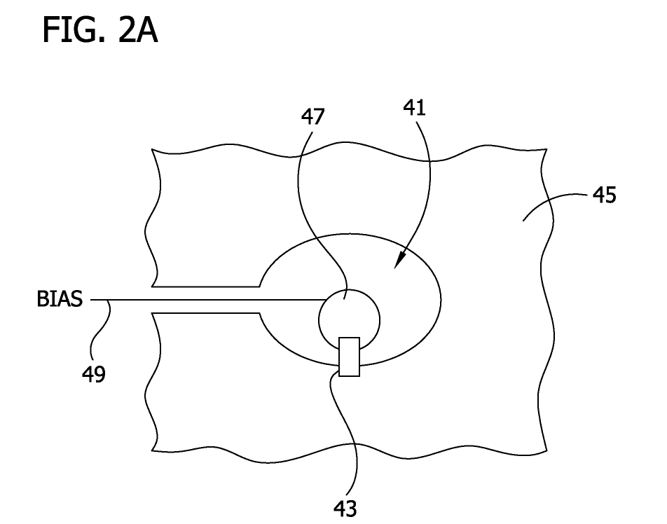

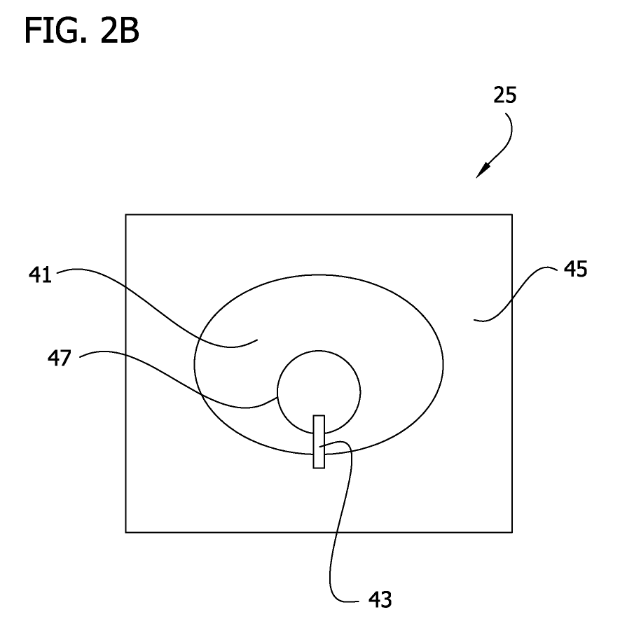

Referring now to FIG. 1, an imaging system 21 embodying aspects of the invention provides a robust and highly sensitive system, especially for use at relatively high frequencies such as those in the microwave and millimeter wave regions of the electromagnetic spectrum (i.e., greater than ultra high frequency). In at least one embodiment, the imaging system 21 includes an array 23 for sampling an electric field. The array 23, also referred to as a “retina,” has many array elements, or sensors 25, distributed over the retina's spatial extent. As described in greater detail below, an embodiment of the microwave and millimeter wave imaging system 21 implements its sensors 25 using modulated slot antennas (see FIG. 2A and FIG. 2B) cut into or otherwise formed in a conducting screen, printed-circuit board (PCB) substrate, or the like.

Advantageously, modulating the slots allows each slot in the array 23 to tag or otherwise identify its own output signal with a unique code for distinguishing one slot from another. Microwave sensing and imaging techniques have shown great utility for a wide range of applications. Reflectometers using probes with small apertures as transmitting/receiving antennas are often used in near-field nondestructive testing (NDT) and imaging applications. For these purposes, a probe aperture (i.e., a modulated slot) is scanned over the sample under test (SUT) and the measured output signal (magnitude and/or phase) is mapped into a two-dimensional intensity raster image. Rapid, cost effective, and high-resolution microwave and millimeter wave imaging systems can be implemented using array of modulated elements (scatterers). Basically, modulation allows the array element to “tag” its own signal, which provides a means for the receiver to identify the location from which the signal was received, i.e., spatial multiplexing, as well as enhances the overall SNR through locked detection and averaging.

According to aspects of the invention, imaging system 21 produces substantially real-time images of virtually any object 29 present in the system's field-of-view. When illuminated by the electromagnetic field, the target object 29 causes at least some of the field to scatter in different directions as a function of the object's material and geometrical properties. For instance, the illuminating electromagnetic field is associated with incident or irradiating microwaves or millimeter waves. Because microwaves and millimeter waves penetrate into dielectric materials, the imaging system 21 can view the interior of an object that comprises such a material. Likewise, imaging system 21 can detect and image an object concealed or otherwise located inside of a dielectric material. The imaging system 21 measures the scattered electric field at a number of discrete locations corresponding to a defined spatial domain (e.g., a planar, cylindrical, spherical, or arbitrarily shaped portion of a plane) located away from the object 29.

The imaging system 21 also permits inspection of a source of electromagnetic radiation. For example, object 29 may itself emit microwave and/or millimeter wave electromagnetic radiation that can be measured at array 23.

Depending on the desired usage of system 21, sensor array 23 can be custom-designed to take different shapes. For example, array 23 can be made of one-dimensional, two-dimensional, or three-dimensional distributions of sensors 25. In an alternative embodiment, sensor array 23 can be made of a flat or an arbitrarily curved conducting surface (any shape that is conformed to a rectilinear or curvilinear grid (rectangle, square, triangle, circle, arc, cone, box, hemisphere, sphere, etc.)). FIG. 1 illustrates an exemplary two-dimensional array of sensors 25 arranged in a rectangular pattern.

As shown in FIG. 1, the array 23 is integrated with other system components, which include a display 31 as well as a receiver 35 and a processor 37. The receiver 35 receives a signal from each sensor element in the array 23 and communicates this information to the processor 37. Because the sensors' output signals are distinguishable from each other, processor 37 knows which signal that receiver 35 receives from which sensor 25. In an embodiment, system 21 utilizes a single receiver 35 for receiving signals from multiple sensors 25. By properly arranging (both spatially and electronically) the signals received at receiver 35 from sensors 25, processor 37 obtains a sampled version, or map, of the actual electromagnetic field incident upon the area of the array 23 from the object 29 being imaged. The processor 37 subsequently processes this map to generate an image of the illuminated object 29. The processor 37, which is responsible for arranging the signals received from each sensor 25 and performing any higher level processing, controls the system timing for electronic tagging and synchronization.

Using special processing of the measurements at the discrete locations (i.e., at the locations of sensors 25), system 21 generates an image of the object's spatial and/or dielectric profiles on a display 31. For example, imaging system 21 generates and displays a multi-dimensional (i.e., two-dimensional or three-dimensional) image of object 29, such as a holographical image.

FIG. 2A illustrates an exemplary slot 41 suitable for use as one of the sensors 25. Loading the slot 41 with an electronically or optically controllable load permits modulating the signal passed by the slot to distinguish the electromagnetic field measured at this location from that measured at a different location. In this instance, an active element 43, such as a diode, is electrically connected across the slot 41 for loading and, thus, modulating the slot 41. As an example, each slot 41 is cut into a conductive screen 45 according to a pattern defining array 23. The active element 43 (e.g., PIN (Positive Intrinsic Negative) diode, varactor diode, photodiode) electrically connects the conductive screen 45 at an edge margin of the respective slot 41 to a conductor 47 positioned within the periphery of each slot 41. In one embodiment, slot 41 is elliptical in shape but it is to be understood that slot 41 could have any number of shapes, including circular. And as described in greater detail below, slot 41 is built on, for example, a PCB having at least one conductive (e.g., copper) layer. If the PCB containing the slot has more than one copper layer, the copper areas surrounding the slot on the back and front of the board may be connected to each other using vias.

In the illustrated embodiment, direct electrical or optical biasing changes the electronic load value of the active element 43. For electrical load control, a dedicated bias line 49 routed to each individual load (or a matrix switch) provides a biasing voltage in the illustrated embodiment. DC bias controls the diode impedance; basically switching the diode ON and OFF. For a PIN diode, for example, applying a zero or negative DC bias voltage across the diode junction turns the diode OFF so that the respective slot 41 outputs a signal representative of the electric field at its location in the array 23. When it is forward biased, the PIN diode turns ON thus blocking the output from the respective slot 41. Loading the slot 41 in this manner essentially changes the slot's capacitance, which in turn changes its resonant frequency. In one embodiment, the active element 43 is electrically connected to a corresponding one of the slots 41 at the location of its maximum elecric field strength.

As described in greater detail below, the size, the shape and spacing of slots 41 depends on certain operational characteristics of imaging system 21. For example, the slot 41 of FIG. 2A has a length greater than its width (length=0.1866 inches; width=0.1400 inches). In this example, the conductor 47 has a radius of 0.0311 inches and is located midway along the length of slot 41. The center of conductor 47 is positioned 0.0228 inches off-center relative to the width of slot 41. The bias line 49 resides in a channel in conductive screen 45 (0.0160 inches from the edge of the channel).

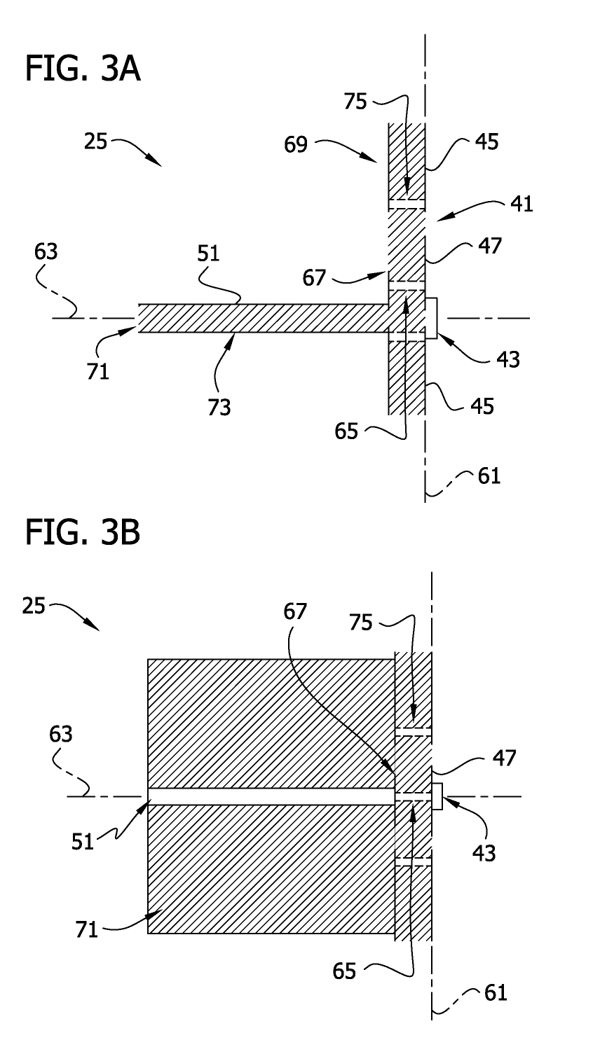

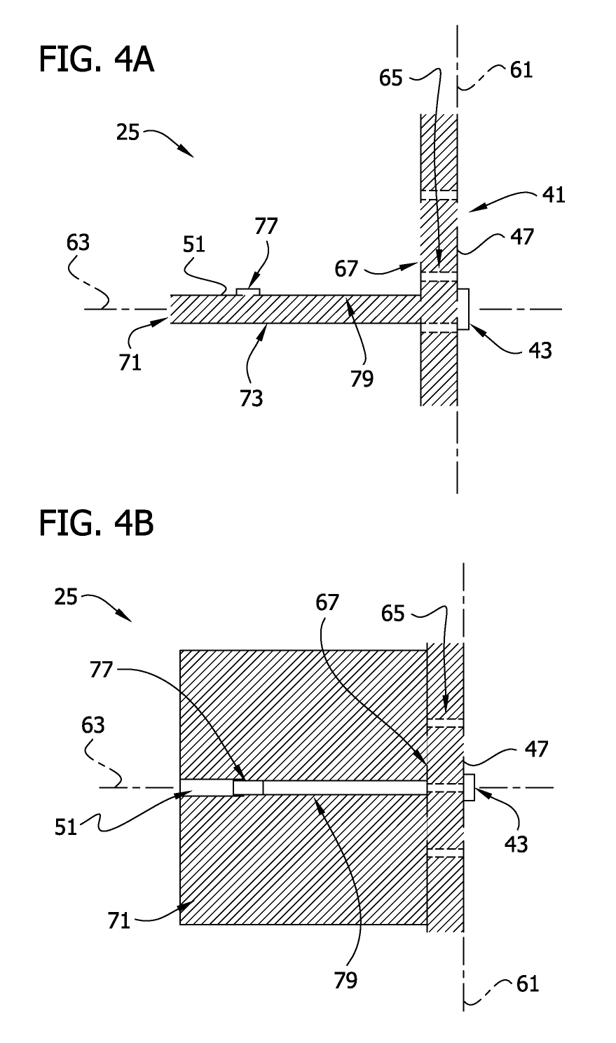

In FIG. 2B, an out-of-plane transmission line 51 (see FIGS. 3A and 3B) feeds the exemplary slot 41. As described above, cost-effective design of non-destructive imaging systems benefit from a switched transmit/receive array, such as array 23, comprised of efficient antenna elements. The transmission line 51 is, for example, a quasi-TEM mode printed transmission line (such as a microstrip line, stripline, or coplanar waveguide (CPW)), a TE, TM or hybrid mode waveguide (such as a rectangular waveguide, circular hollow waveguide, or dielectric waveguide), or a TEM mode coaxial line.

Because imaging arrays are typically planar and utilize a large number of closely-spaced elements, the performance of these systems depends largely on the efficiency of the array elements and their feeding structures. Moreover, isolation among the elements and isolation between transmitting the output signal and receiving the feed is important. Implementing efficient feeding and high-isolation switching, in-plane with the elements of a compact array is rather challenging at high microwave frequencies (e.g., 24 GHz). Advantageously, the resonant switched-slot sensor 25, such as shown in FIG. 2B, has an out-of-plane feed and provides an efficient element for microwave imaging arrays. In the illustrated embodiment, slot 41 is loaded with, for example, a PIN diode, generally indicated 43 in the illustrated embodiment. In this embodiment, sensor 25 is switched directly.

According to aspects of the invention, a microwave switched-slot probe, such as sensor 25, provides many advantages. For example, the resonant slot 41 and, thus, sensor 25, has a small form-factor. Also, resonant slot 41 exhibits low mutual-coupling between various array elements. Furthermore, due to high modulation efficiency, the SNR can be maximized leading to enhanced measurement sensitivity.

Individually coupling the signals transmitted into and received from each loaded slot 41, using an out-of-plane transmission line 51, increases the overall system efficiency by achieving a higher degree of isolation between any two adjacent slots 41 of array 23, including when a single transmission line, such as a waveguide, feeds a set of slots 41. According to aspects of the invention, the illustrated embodiment enables system 21 to operate in monostatic mode in a much more efficient and simpler fashion than other arrays. Two design variations of this out-of-plane feeding structure are disclosed herein, namely, electrical and electromagnetic coupling. Connecting the transmission line to the load of the slot using an electrically conducting element such as a coupling via provides direct electrical coupling. On the other hand, a proximity effect transfers electromagnetic energy to the slot for magnetic coupling.

Referring now to FIGS. 3A and 3B and FIGS. 4A and 4B, aspects of the invention involve feeding the modulated slot 41 (e.g., PIN diode-loaded slot) with transmission line 51. In the illustrated embodiments, slot 41 is elliptical in shape but it is to be understood that slot 41 could have any number of shapes, including circular.

The transmission line 51 shown in FIGS. 3A and 3B and FIGS. 4A and 4B is a microstrip line generally orthogonal to the plane of slot 41. As shown, the conductive surface 45 having slot 41 formed therein defines a first plane 61. The transmission line 51 is oriented in a second plane 63, which is different than and non-parallel to the first plane 61. A microstrip line, for example, is a suitable transmission line because its electromagnetic field is concentrated in the location of active element 43 (i.e., a PIN diode) in the slot 41. This arrangement lends itself to a compact probe suitable for use in high-resolution two-dimensional imaging arrays. In addition, mutual coupling between shielded feeding elements is reduced.

When designing such a loaded or switched-slot 41, issues concerning impedance matching between the slot 41 and the feed provided on line 51 and radiation and modulation efficiencies are considered. In FIGS. 3A and 3B, a direct microstrip line connection to a circular load, such as conductor 47, of slot 41 provides electric coupling using an electrically conductive element such as a via 65. A coupling pad 67 is sized and shaped to facilitate (and optimize) efficient electromagnetic energy transfer from transmission line 51 to slot 41. FIGS. 3A and 3B further illustrate a back slot plane 69 corresponding to a front slot plane at the surface 45, which defines the plane 61. As shown, sensor 25 includes a dielectric substrate 71 separating the front and back slot planes 61, 69. The dielectric substrate 71 also separates the microstrip transmission line 51 from its corresponding ground plane 73. In this embodiment, a grounding via 75 connects the front slot plane at surface 45 with the back slot plane 69.

Although similar to the embodiment of FIGS. 3A and 3B, the sensor 25 as shown in FIGS. 4A and 4B includes an inline switch 77 and an impedance transformer 79. Advantageously, incorporating switches, such as switch 77, into the out-of-plane feeding transmission lines enhances the isolation among the elements of array 23. The impedance transformer 79 permits matching the relatively high impedance of slot 41 (e.g., hundreds of ohms) to the impedance of transmission line 51 (e.g., 50Ω typical of RF circuitry). In one embodiment, impedance transformer 79 is a resonant type designed to match the resonance frequency of the slot 41. In an alternative embodiment, sensor 25 of FIGS. 4A and 4B includes a wideband impedance transformer 79.

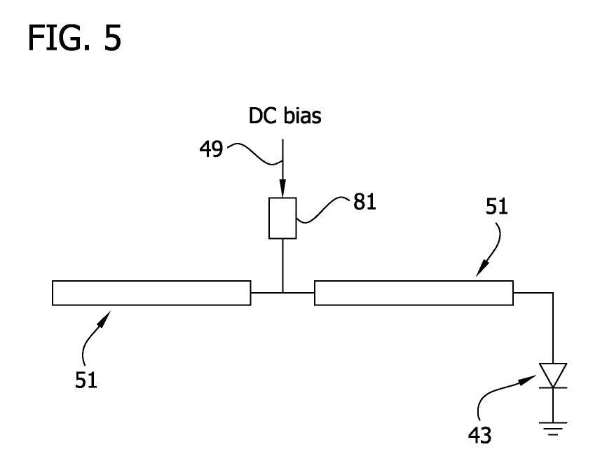

With electrical coupling between the slot 41 and the microstrip transmission line 51, it is possible to DC bias the PIN diode 43 through the feeding transmission line 51 as shown in FIG. 5. FIG. 5 also shows the DC bias on line 49 fed through an RF choke 81.

An array element design embodying aspects of the invention involves coupling the signals transmitted into slot 41 and the signals received signals from slot 41 using a microstrip feed substantially perpendicular to the plane of the slot 41. It is to be understood that benefits of the an out-of-plane feed may be achieved at angles other than 90°.

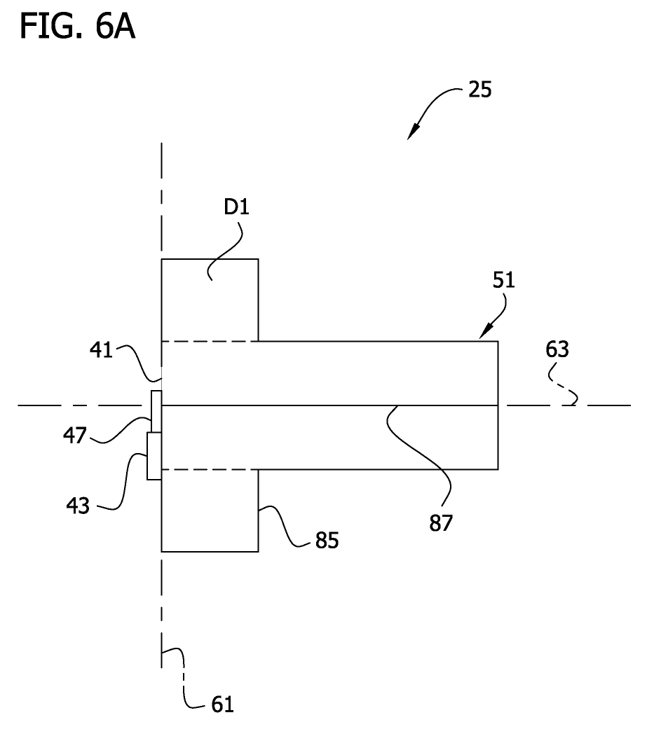

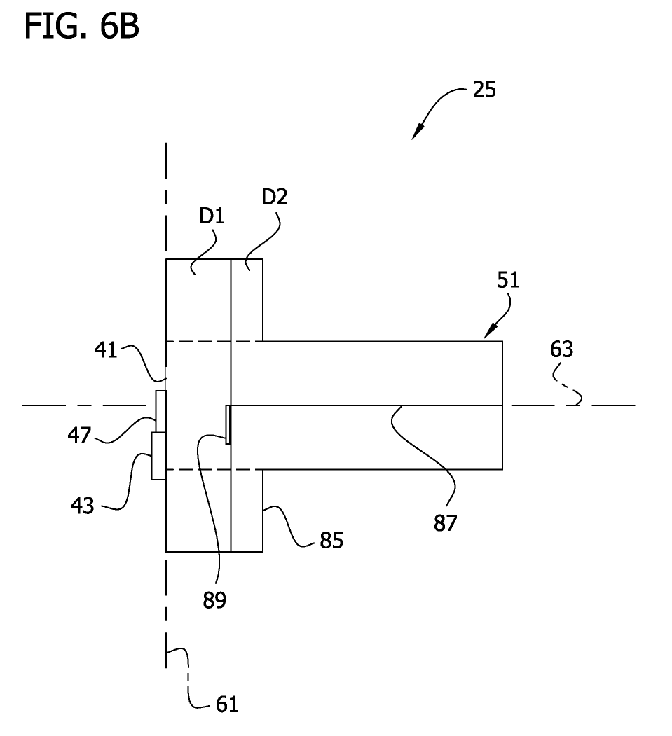

Referring now to FIGS. 6A and 6B, aspects of the invention involve feeding the modulated slot 41 (e.g., PIN diode-loaded slot) with transmission line 51. In one embodiment, transmission line 51 is generally orthogonal to the plane of slot 41. As shown, the conductive surface 45 having slot 41 formed therein defines the first plane 61. Transmission line 51 is oriented in the second plane 63, which is different than and non-parallel to the first plane 61. A coaxial line, for example, is a suitable transmission line because the aperture of slot 41 is similar to the cross-section of the coaxial line, enabling an easier matching between the out-of-plane transmission line 51 and the slot antenna, that is, sensor 25. This arrangement lends itself to a compact probe suitable for use in high-resolution two-dimensional imaging arrays. In addition, mutual coupling between shielded feeding elements is reduced.

When designing such a loaded or switched-slot 41, issues concerning impedance matching between the slot 41 and the feed provided on line 51 and radiation and modulation efficiencies are considered. In FIG. 6A, a direct coaxial line connection to slot 41 provides electric coupling. In FIG. 6B, connection through proximity effect provides electromagnetic coupling.

An array element design embodying aspects of the invention involves coupling the signals transmitted into slot 41 and the signals received signals from slot 41 using a coaxial feed substantially perpendicular to the plane of the slot 41. It is to be understood that benefits of the an out-of-plane feed may be achieved at angles other than 90°. Two design variations of this out-of-plane feeding structure are disclosed herein, namely, direct electrical and electromagnetic coupling. Simulation and measurement results show that high radiation efficiency and increased switching isolation, due to switches on the feed line, can be obtained with these feed designs.

FIGS. 6A and 6B show the schematic of two different feeding schemes, each utilizing a coaxial feed line. The inductive elliptical (or circular) slot 41 and the capacitive gap element 43 between the circular load (i.e., conductor 47) and the slot 41 result in a resonant structure. In both probes, namely, sensor 25 as shown in FIG. 6A and sensor 25 as shown in FIG. 6B, a coaxial line feeds slot 41 through a transition slot that is cut into the conductive plane 45 of the opposite side of a PCB 85.

In FIG. 6A, a center conductor 87 of the coaxial feed, i.e., transmission line 51, is connected to the circular conductor 47 through a via in the two-layer PCB 85. In an alternative embodiment, as shown in FIG. 6B, sensor 25 comprises a four-layer (two dielectric layers D1 and D2) PCB 85 and two additional transition slots. The end of the internal conductor 87 of the coaxial line is connected to a pin that passes through a via in the second dielectric layer and terminates in an open-circuit stub 89 located between the two dielectric layers D1 and D2. Consequently, sensor 25 as shown in FIG. 6A has a direct connection between the coaxial feed and slot 41, while sensor 25 as shown in FIG. 6B employs proximity feed.

Simulating a practical K-band slot on a printed-circuit-board reveals various attributes of the designed switched-slot probes with perpendicular coaxial feeds. For example, a lossy conductor, i.e., copper, and Rogers R04350 board (∈ᵣ=3.48, tan δ=0.004) (for the probe of FIG. 6A) and Rogers RT5880 board (∈ᵣ=2.2, tan δ=0.0009) (for the probe of FIG. 6B). The active element 43, a PIN diode in this example, is modeled in the ON and OFF states as a lumped element with impedance of 5Ω and −j265Ω, respectively. In the simulations, a 50Ω coaxial line with internal and external diameters of 1.3 mm and 4.1 mm, respectively, filled with Teflon (∈ᵣ=2.08, tan ∈=0.004), feeds the slot 41. Other parameters of the probes are listed in Table I, below (where Probe I represents sensor 25 as shown in FIG. 6A and Probe II represents sensor 25 as shown in FIG. 6B):

TABLE 1

| | Slot major/minor | Load | Thickness of | Thickness of | Via |
|---|---|---|---|---|---|
| Probe | radius, mm | radius, mm | layer 1, mm | layer 2, mm | radius, mm |
| I | 2.21/2.01 | 1.22 | 1.91 | — | 0.73 |
| II | 2.04/2.04 | 1.32 | 0.69 | 0.25 | 0.13 |

It can be seen from the Table 1 that the slots 41 are small (the largest dimension of the slots is less than half-wavelength). Design optimization for the Probe II of FIG. 6B resulted in a stub length of −1 mm and a width of −0.8 mm.

When active element 43 is OFF, slot 41 radiates at the design frequency (slot is “open”), i.e., signals at the resonant frequency pass through the slot. When active element 43 is ON, it “shorts” the gap between the circular load 47 and the edge of slot 41. As a result, slot 41 does not resonate at the frequency of interest. In this state, slot 41 does not allow any signal to pass through, i.e., the slot is “closed.” At the resonant frequency, the minimum response of the probe of FIG. 6A is around −28 dB at 22.2 GHz and the minimum response of the probe of FIG. 6B is around −24 dB at 24 GHz when active element 43 is OFF. When the active element is ON, the minimum response of the probe of FIG. 6A is around −0.5 dB at 22.2 GHz and the minimum response of the probe of FIG. 6B is around −0.4 dB at 24 GHz. This means that there is a good matching between slot 41 and the feed on transmission line 51 for both probes and that the active element 43 (i.e., the PIN diode) shorts the slot efficiently when it is ON. In this manner, sensor 25 achieves maximum modulation efficiency and, advantageously, radiation efficiency is high for both probes, while the leakage is low.

The probes fed by out-of-plane transmission line 51 have wide beams in principle planes (E- and H-planes). Calculating modulation efficiency (in dB) from the difference in total efficiencies when the diode is ON and OFF reveals that modulation efficiency is relatively high for both probes (it is higher for the probe of FIG. 6B than for the probe of FIG. 6A (13.6 dB vs. 11.6 dB)). In practice, however, modulation efficiency may be reduced due to signal leakages (when the slot is closed) and losses (when the slot is open).

Additional analysis of the field near the slot shows that, when the diode is in the OFF state (slot is open), the slot fields were mainly linearly polarized.

Referring further to FIG. 2A and FIG. 2B, active element 43 functions to modulate its corresponding slot 41. In this manner, sensor 25 comprises a switched-slot sensor, or probe. When active element 43 is OFF, slot 41 passes a signal representative of the electric field incident on the array 23 at its location. But when active element 43 is ON, slot 41 does not pass such a signal. The processor 37 triggers operation of active element 43 to modulate slot 41 and, thus, tag its signal with information identifying its location relative to the other sensors 25 of array 23.

As arranged to form array 23, the plurality of slots 41 provide for high measurement sensitivity and spatial resolution at relatively higher frequencies. The array 23, which includes modulated slots 41 cut into conductive screen 45 (e.g., a metal plate) is unpredictably well-suited for electric field mapping at microwave and millimeter wave frequencies. Conventional imaging systems, by contrast, avoid materials such as conducting metals around active elements because of their tendency to reflect back the electromagnetic waves. The array 23 is subsequently integrated with other system components, including receiver circuitry, processing circuitry, and display circuitry (i.e., receiver 35, processor 37, and display 31, respectively). Using special processing of the measurements at the discrete locations, the system 21 generates multi-dimensional images of the object's spatial and/or dielectric profiles (e.g., holographical images).

In one embodiment, the array sensors 25 (i.e., modulated slots 41) are placed within close proximity of each other to provide appropriate sampling of the electromagnetic field from object 29. Moreover, the design of slot 41 beneficially affords weak mutual coupling between adjacent slots. Using the slot 41 as an array element (i.e., sensor 25) allows for optimizing electromagnetic field sampling performance by reducing the spacing and mutual coupling between the sensors 25, which are otherwise two opposing objectives. Each of the sensors 25 passes a signal proportional to the field at the particular element's location in array 23.

By detecting relatively small changes in the electric field over the area of sensor array 23, the imaging system 21 permits highly sensitive observation of subtle object features in the obtained image. Moreover, imaging system 21 rapidly samples the electric field to provide substantially real-time operation. And because sensor array 23 is relatively compact and has closely-spaced sensors 25 in at least one embodiment of the invention, imaging system 21 provides images of high fidelity and spatial resolution.

The sensors 25, embodied by slot antennas 41 and incorporated into array 23, may take various designs, such as sub-resonant slots or resonant slots, depending on the particular application of the system 21. Moreover, available modulation types include sequential, parallel, and hybrid. Sequential modulation involves modulating one slot at a time while parallel modulation involves modulating a plurality of slots at the same time (e.g., using orthogonal modulation codes). In a hybrid modulation type where some slots are modulated in parallel and some are sequentially modulated, different modulation patterns are possible.

Further aspects of the invention relate to loading the modulated slots 41 with active element 43 to affect the transmission properties of the slots. For example, modulated slots 41 can be resonant, sub-resonant, wide-band, reconfigurable resonant, and shape reconfigurable. Resonant slots have a compact design (e.g., slot spacing less than λ₀/2, where λ₀ is the free space wavelength) and are narrow-band but have a relatively high sensitivity. In other words, slots 41 open and close efficiently at a single frequency. Sub-resonant modulated slots are similarly compact in design with a relatively low sensitivity but can be used over a wider range of frequencies. Efficiency is a trade-off of a wider band of operation. Wide-band slots are larger elements with moderate sensitivity over a range of frequencies. As an example, slot spacing between wide-band slots is in the order of λ₀/2. Advantageously, the wider band of frequencies permits holography. Reconfigurable resonant slots are resonant slots with variable loading conditions (e.g., through the use of varactor diodes, PIN diodes, and the like) to control the resonance frequency for swept frequency operation. In other words, electrically loading the slots, through the use of one or more additional active elements, changes the resonant frequency of the slots in a predictable and well-controlled manner. Shape reconfigurable slots have fixed sizes larger than may be needed and are loaded with multiple PIN diodes that are selectively activated to electronically change the slot dimensions and hence its frequency response (i.e., narrow-band vs. wide-band operation). For example, a shape reconfigurable slot of 1 cm in length may have an active element located every 1 mm. By loading the slot differently at different positions (depending on which of the several elements are used to load the slot), selected discrete or overlapping portions of the slot may be opened and closed.

In an alternative embodiment, the shape reconfigurable slots are constructed out of a highly spatial selective screen material, such as a liquid-crystal polymer (LCP), so that narrow-band as well as wide-band slots can be realized. This design is based on locally changing the effective permittivity of the LCP via electrical control. Independent and localized changes in permittivity of the LCP create the pixels (i.e., slots) that are used to sample the scattered field. Those skilled in the art are familiar with LCP materials, which have electrical characteristics responsive to an applied voltage.

Referring again to FIG. 1, processor 37 decodes the signals obtained via array 23 by receiver 35 to generate the image of object 29 and to generate control signals for modulating sensors 25. In one embodiment, processor 37, in the form of a computer, interfaces with array 23 via a data acquisition (DAQ) card and executes software to generate control signals, including modulation signals. The DAQ card acquires the modulated sensor signals from pickup circuitry (i.e., receiver 35) and subsequently processes and decodes the signals in software. Each of the decoded signals is arranged according to its respective slot location for displaying on the computer's screen, that is, display 31.

Alternatively, a high speed digital signal processor (DSP), which interfaces with an analog-to-digital converter and display 31, embodies processor 37.

In yet another alternative embodiment, processor 37 comprises a custom-made circuit, such as a digital switching network made from discrete components or a field programmable gate array, for generating the control signals. Each modulated sensor signal is decoded in hardware using analog or digital processing techniques. The processor 37 acquires the decoded signal via a ADC (Analog to Digital Converter) card or the like for processing the sampled measurements and generating the image for display.

One skilled in the art will recognize that various combinations of the integration schemes described above may be used to generate the control signals and decode the resulting modulated signals without deviating from the scope of the invention. System integration allows for a portable imaging system 21 to be deployed. In addition, one or more of the interfaces between the system components are wireless interfaces (e.g., the signal can be acquired or displayed remotely).

Aside from the raw image of the electric field map over the retina area (i.e., the area of array 23), imaging system 21 applies spatial and/or temporal focusing techniques (e.g., synthetic aperture focusing, back-propagation, beam-forming, holographic techniques, etc.) known to those skilled in the art to obtain two-dimensional and three-dimensional profiles of the geometry/shape and the dielectric properties of the imaged object 29.

Advantageously, using out-of-plane (including orthogonal) feeding in the design of array 23 allows switches to be incorporated into the feeding transmission line to enhance the isolation between the array elements. Moreover, an impedance transformer, such as transformer 79, permits matching of the relatively high impedance slots (typically hundreds of ohms) to a standard 50Ω transmission line often used in RF circuitry. According to one or more embodiments of the invention, the impedance transformer is a resonant type designed to match the resonance frequency of the slots or, alternatively, it is made wideband. Signal combiners or dividers (e.g., a Wilkinson combiner) permit building a slot array with a single port. In addition, the out-of-plane feed can be implemented in a multiplexer, or network of combiners. Radio-frequency integrated circuits (RFIC's), such as switches, amplifiers, and mixers, are readily incorporated in the multiplexer with out-of-plane feed. In yet another embodiment, feeding array 23 with out-of-plane microstrip and/or CPW printed transmission lines enables the use of small size surface mount RFIC's along with the tight special requirements of the imaging array.

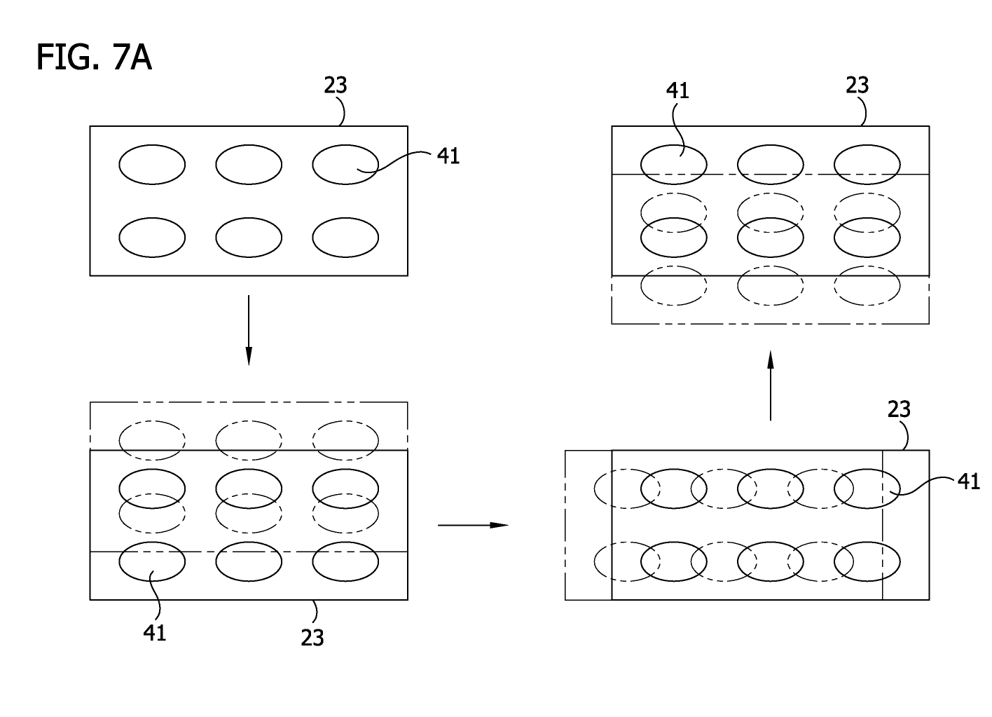

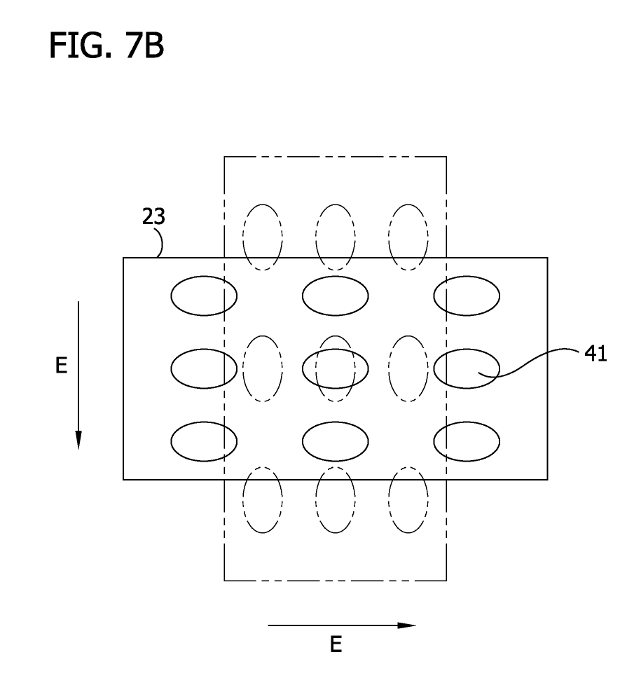

Referring now to FIGS. 7A and 7B, aspects of the invention enhance the performance of the imaging system 21 to obtain higher resolution and/or sensitivity and the like. For example, array 23 is scanned (i.e., mechanically moved) and/or arranged with similar sensor arrays to obtain three-dimensional maps of the scattered electric field. Alternatively, array 23 is displaced in two orthogonal directions to increase the number of samples obtained per wavelength. In other words, imaging system 21 includes means for providing translational movement of array 23, generating the images of object at each position and processing these images to obtain an image with higher spatial resolution and fidelity.

The array 23 of FIG. 7A has a plurality of slots 41 (e.g., six slots are shown in FIG. 4A for convenience). It is to be understood that array 23 may include any number of slots 41. For example, the positions of six slots of array 23 are shown in FIG. 4A undergoing one or more translational displacements. In the illustrated embodiment, array 23 is first shifted down, across, and then up, with the previous position being indicated by broken lines. The horizontal displacement may be to the right or to the left. Performing the displacement, image generation, and signal processing actions quickly allows the imaging process to remain in real time. As an example, the displacement is a half the sensors' spacing.

Referring now to FIG. 7B, the modulated slots 41 in one embodiment are sized and shaped to be linearly polarized. For example, modulated slot 41 as shown in either FIG. 2A or FIG. 2B has a generally longitudinal shape that passes a component of the scattered electric field in one direction but blocks components of the field in other directions. According to aspects of the invention, measuring the scattered electric field at different polarizations increases the amount of geometrical and materials information revealed about the imaged object 29. Because polarization involves the spatial orientation of the electric field, the imaging system 21 can be designed to measure electric fields at its array 23, or retina, in several polarizations. The ability to measure different polarizations increases the amount of information revealed about the imaged object 29. For example, sensors 25 each comprise a linearly polarized modulated slot 41 to measure a component of the electric field. Using linearly polarized modulated slots 41 allows array 23 to measure the scattered electric field in an orthogonal direction by rotating the retina 90 degrees about a central point as shown in FIG. 4B from a vertical polarization to a horizontal polarization (shown with broken lines). Again, performing the rotation action quickly allows the imaging process to remain in real time. It is to be understood that the amount and direction of rotation may vary according to the implementation of imaging system 21.

Alternatively, two sets of linearly polarized sensor elements arranged in the retina space allow measurements of two orthogonal electric field components (sequentially or simultaneously). In this alternative embodiment, the sensors 25 in one set comprise slots 41 oriented along a first direction and the sensors 25 in the other set comprise slots 41 oriented along a second direction that is orthogonal to the first direction. In yet another alternative embodiment, sensors 25 comprise dual-polarized sensor elements with electrical control over the polarization for measuring two orthogonal electric field components (sequentially or simultaneously).

In another embodiment array 23 is scanned (i.e. mechanically moved) to obtain higher spatial resolution and/or to increase the dimensions of irradiating area. For example, array 23 with the two sets of the sensors 25 or linear array 23 can be translationaly moved near the object.

The general operation described above is independent of the source of illumination (e.g., an antenna) and, depending on the source of electromagnetic field illumination, different modes of operation are possible. Unlike the human eye's retina, which only receives the light energy scattered from objects, the sensor array 23, or retina, may be used for transmitting, in addition to receiving, microwave and/or millimeter wave energy. The imaging system 21 can be passive in the sense that it receives signals representative of an electric field generated by an independent source and scattered by object 29. In this passive mode, an independent source produces the illuminating field so imaging system 21 can obtain a spatial map of the scattered electric field. Generally, this independent source is outside the retina spatial domain and not part of array 23. Similarly, object 29 itself emits electromagnetic radiation independently of imaging system 21. On the other hand, in an active operational mode, the source of the illuminating electric field is part of the imaging system 21. When operating in the active mode, one or more sensors 25 constitute a radiating source built within the retina region for illuminating object 29 as array 23 samples the scattered electric field. The active mode provides a wide breadth of use in many applications and promotes portability because different patterns corresponding to different locations and distributions may be generated. It is to be understood that the configuration of FIG. 1 is merely exemplary and various configurations are contemplated within the scope of the invention. For example, the target object 29 may be positioned between an external electric field source and the array 29 as shown in FIG. 1. In yet another alternative embodiment, the electric field radiates from the array 23 itself, strikes object 29, and then is scattered back toward array 23.

Referring again to FIG. 1, receiver 35 is capable of working as a transceiver (receiver/transmitter) depending on the mode of operation (active/passive). For passive operation, receiver 35 works as receiver only (listening only). In the active mode, receiver 35 also has an electric field source that provides the illuminating signal through an antenna or the like. In this instance, receiver 35 not only initiates the transmitted signal but also receives the signals from the array 23 and puts them in a form suitable for further processing (e.g., pre-conditioning and down-conversion) by processor 37.

The microwave and millimeter wave imaging system 21 is useful in at least the following applications.
A. Rapid electric field measurements for antenna pattern measurements, specific absorption rate (SAR) measurements and radar cross section (RCS) measurements.
B. General microwaves and millimeter waves imaging.
C. Nondestructive testing of dielectric composites and material characterization.
D. Target localization and angle of arrival estimation.
E. Anti-collision devices.
F. EMI & EMC.
G. Ultra-wide band microwave and millimeter wave communication links.
H. Surveillance and security systems.
I. Detection of contraband.

According to aspects of the invention, switched-slot sensor 25 for use in sensor array 23 includes conductive surface 45. The conductive surface 45 has slot 41 formed therein and active element 43 is connected across the slot. The transmission line 51 is oriented substantially perpendicular to conductive surface 45 near slot 41 and provides a feed coupled to active element 43 for selectively modulating the slot 41. In this instance, an output signal from the sensor 25 is representative of an electric field detected at the modulated slot 41.

An imaging system 21 embodying aspects of the invention comprises sensor array 23, which has a plurality of switched-slot sensors 25 for detecting an electric field from object 29. The sensors 25 are positioned at locations corresponding to a defined spatial domain located remotely from object 29. Also, the sensors 25 each provide an output signal representative of the electric field detected at the respective location of the sensor. Each of the sensors 25 includes conductive surface 45 defining a first plane. The conductive surface 45 has slot 41 formed therein and active element 43 is connected across it. The transmission line 51 is oriented in a second plane that is different than and non-parallel to the first plane. The transmission line 51 provides a feed coupled to active element 43 for selectively modulating slot 41. The imaging system 21 further comprises a receiver 35 operatively connected to array 23 for receiving the output signals from sensors 25 and processor 37 configured to generate a multi-dimensional profile representative of the object 29 in the defined spatial domain based on the received output signals. Moreover, imaging system 21 includes display 31 for displaying an image of the multi-dimensional profile.

A method embodying aspects of the invention generates a multi-dimensional profile of object 29. The method comprises illuminating object 29 with an electric field that includes electromagnetic energy having a frequency greater than ultra high frequency scattered by object 29 illuminated thereby. The method also includes sampling the scattered electric field at a plurality of locations via a plurality of switched-slot sensors 25. The locations correspond to a defined spatial domain located remotely from object 29. And each of the sensors 25 comprises active element 43 connected across slot 41 and transmission line 51. The slot 41 defines a first plane and the transmission line 51 is oriented in a second plane different than and non-parallel to the first plane. The method further comprises receiving output signals from sensors 25 and generating a multi-dimensional profile representative of object 29 in the defined spatial domain based on the received output signals from the sensors 25.

In another embodiment, switched-slot sensor 25, for use in sensor array 23, includes conductive surface 45, active element 43, and transmission line 51. The slot 41 formed in conductive surface 45 has active element 43 connected across the slot and an out-of-plane transmission line 51 coupled to active element 43 provides a feed for selectively modulating the slot 41 and transmits an output signal representative of an electric field detected at the modulated slot 41.

In yet another embodiment, imaging system 21 comprises a plurality of switched-slot sensors 25 positioned at locations corresponding to a defined spatial domain located remotely from the object 29. The sensors 25, receiving and responsive to electromagnetic energy at a frequency greater than ultra high frequency, detect an electric field from object 29. Each of the sensors 25 includes conductive surface 45 defining a first plane. The conductive surface 45 has slot 41 formed therein and active element 43 is connected across it. The transmission line 51 is oriented in a second plane that is different than and non-parallel to the first plane. The transmission line 51 provides a feed coupled to active element 43 for selectively changing the resonant frequency of the slot 41 and transmits an output signal representative of the electric field detected at the respective location of the sensor as a function of the slot's resonant frequency. The imaging system 21 further comprises receiver 35 operatively connected to sensors 25 for receiving the output signals representative of the electric field detected at the plurality of locations and processor 37 configured to generate a multi-dimensional profile representative of object 29 in the defined spatial domain based on the received output signals.

The order of execution or performance of the operations in embodiments of the invention illustrated and described herein is not essential, unless otherwise specified. That is, the operations may be performed in any order, unless otherwise specified, and embodiments of the invention may include additional or fewer operations than those disclosed herein. For example, it is contemplated that executing or performing a particular operation before, contemporaneously with, or after another operation is within the scope of aspects of the invention.

Aspects of the invention may be implemented with computer-executable instructions. The computer-executable instructions may be organized into one or more computer-executable components or modules. Aspects of the invention may be implemented with any number and organization of such components or modules. For example, aspects of the invention are not limited to the specific computer-executable instructions or the specific components or modules illustrated in the figures and described herein. Other embodiments of the invention may include different computer-executable instructions or components having more or less functionality than illustrated and described herein.

When introducing elements of aspects of the invention or the embodiments thereof, the articles “a,” “an,” “the,” and “said” are intended to mean that there are one or more of the elements. The terms “comprising,” “including,” and “having” are intended to be inclusive and mean that there may be additional elements other than the listed elements.

Having described aspects of the invention in detail, it will be apparent that modifications and variations are possible without departing from the scope of aspects of the invention as defined in the appended claims. As various changes could be made in the above constructions, products, and methods without departing from the scope of aspects of the invention, it is intended that all matter contained in the above description and shown in the accompanying drawings shall be interpreted as illustrative and not in a limiting sense.

What is claimed is:

1. A switched-slot sensor for use in a sensor array comprising:
a conductive surface having a slot formed therein;
an active element connected across the slot; and
a transmission line oriented substantially perpendicular to the conductive surface near the slot, said transmission line providing a feed coupled to the active element for selectively modulating the slot, wherein an output signal from the sensor is representative of an electric field detected at the modulated slot.

2. The sensor of claim 1, wherein the active element connected across the slot selectively changes the resonant frequency thereof in response to the feed.

3. The sensor of claim 1, wherein the feed is electrically coupled to the active element.

4. The sensor of claim 1, wherein the feed is electromagnetically coupled to the active element.

5. The sensor of claim 1, wherein the transmission line comprises a microstripline.

6. The sensor of claim 1, wherein the transmission line is switched.

7. The sensor of claim 1, wherein the active element comprises a PIN diode electrically connected to the slot and wherein the output signal of the sensor is representative of a phase and magnitude of the electric field detected at the modulated slot.

8. The sensor of claim 1, wherein the conductive surface has a plurality of slots formed therein at locations corresponding to a defined spatial domain located remotely from an object to define the sensor array, each of said slots having a respective active element connected thereacross and a respective feed coupled thereto for selectively modulating each of said slots, and wherein the sensor array measures an electric field from the object.

9. The sensor of claim 8, wherein a processor is configured to generate a multi-dimensional profile representative of the object in the defined spatial domain based on output signals received from the plurality of slots.

10. The sensor of claim 1, wherein the modulated slot comprises one or more of the following types: sub-resonant, resonant, wide-band, reconfigurable resonant, and shape reconfigurable.

11. The sensor of claim 1, wherein the sensor array is responsive to millimeter wave or microwave electromagnetic energy.

12. An imaging system comprising:
a sensor array having a plurality of switched-slot sensors for measuring an electric field from an object, said sensors being positioned at locations corresponding to a defined spatial domain located remotely from the object, said sensors each providing an output signal representative of the electric field detected at the respective location of the sensor, wherein each of said sensors comprises:
a conductive surface having a slot formed therein, said conductive surface defining a first plane;
an active element connected across the slot, and
a transmission line oriented in a second plane different than and non-parallel to the first plane, said transmission line providing a feed coupled to the active element for selectively modulating the slot;
a receiver operatively connected to the array for receiving the output signals from the sensors;
a processor configured to generate a multi-dimensional profile representative of the object in the defined spatial domain based on the received output signals; and
a display for displaying an image of the multi-dimensional profile.

13. The imaging system of claim 12, wherein the active element connected across the slot selectively changes the resonant frequency thereof in response to the feed.

14. The imaging system of claim 12, wherein the feed is electrically coupled to the active element.

15. The imaging system of claim 12, wherein the feed is magnetically coupled to the active element.

16. The imaging system of claim 12, wherein the transmission line comprises microstrip lines.

17. The imaging system of claim 12, wherein the active element comprises a diode electrically connected to the slot.

18. The imaging system of claim 17, wherein diode comprises a PIN diode and wherein the output signal of each of the sensors is representative of a phase and magnitude of the electric field detected at the respective slot modulated by the PIN diode electrically connected thereto.

19. The imaging system of claim 12, wherein the second plane is substantially perpendicular to the first plane.

20. The imaging system of claim 12, wherein the output signal of each of the sensors has a unique identity corresponding to the respective location thereof in the sensor array, and wherein the processor is configured to generate a map of the measured electric field based on the unique identity of each of the output signals.

21. The imaging system of claim 12, further comprising an electric field source for illuminating the object, said electric field comprising electromagnetic energy having a frequency greater than ultra high frequency and being scattered by the object illuminated thereby.

22. A method of generating a multi-dimensional profile of an object, said method comprising:
illuminating the object with an electric field, said electric field comprising electromagnetic energy having a frequency greater than ultra high frequency and being scattered by the object illuminated thereby;
sampling the scattered electric field at a plurality of locations via a plurality of switched-slot sensors, said locations corresponding to a defined spatial domain located remotely from the object, each of said sensors comprising an active element connected across a slot, said slot defining a first plane, each of said sensors further comprising a transmission line oriented in a second plane different than and non-parallel to the first plane;
receiving output signals from the sensors; and
generating a multi-dimensional profile representative of the object in the defined spatial domain based on the received output signals from the sensors.

23. The method of claim 22, further comprising displaying an image of the multi-dimensional profile.

24. The method of claim 22, further comprising providing a feed coupled to the active element of each of the sensors via the transmission line.

25. The method of claim 24, further comprising modulating the slot of each of the sensors by selectively changing the resonant frequency thereof in response to the feed.

26. The method of claim 24, further comprising electrically coupling the feed to the active element of each of the sensors.

27. The method of claim 24, further comprising electromagnetically coupling the feed to the active element of each of the sensors.

28. The method of claim 22, further comprising loading the slot of each of the sensors via the active element electrically connected thereto.

29. The method of claim 22, further comprising orienting the transmission line of each of the sensors relative to the slot of each of the sensors such that the second plane is substantially perpendicular to the first plane.

30. A switched-slot sensor for use in a sensor array comprising:
a conductive surface having a slot formed therein, said surface defining a sensor plane;
an active element connected across the slot; and
an out-of-plane transmission line coupled to the active element, said transmission line providing a feed to the active element for selectively modulating the slot and transmitting an output signal from the sensor, said output signal being representative of an electric field detected at the modulated slot.

31. The switched-slot sensor of claim 30, wherein the transmission line is oriented substantially perpendicular to the conductive surface near the slot.

32. An imaging system comprising:
a plurality of switched-slot sensors positioned at locations corresponding to a defined spatial domain located remotely from the object, said sensors receiving and responsive to electromagnetic energy at a frequency greater than ultra high frequency for detecting an electric field from the object, wherein each of said sensors comprises:
a conductive surface having a slot formed therein, said conductive surface defining a first plane;
an active element connected across the slot, and
a transmission line oriented in a second plane different than and non-parallel to the first plane, said transmission line providing a feed coupled to the active element for selectively changing the resonant frequency thereof to modulate the slot and transmitting an output signal representative of the electric field detected at the respective location of the sensor as a function of the resonant frequency of the modulated slot;
a receiver operatively connected to the sensors for receiving the output signals therefrom representative of the electric field detected at the plurality of locations; and
a processor configured to generate a multi-dimensional profile representative of the object in the defined spatial domain based on the received output signals from the sensors.

33. The imaging system of claim 32, further comprising a display operatively connected to the processor for displaying an image of the multi-dimensional profile generated thereby.

34. The imaging system of claim 32, wherein the electric field comprises microwave or millimeter wave electromagnetic energy.

35. The imaging system of claim 32, wherein the plurality of sensors comprise a sensor array.
